(19) United States
(12) Patent Application Publication
(10) Pub. No.: US 2013/0308255 A1
(43) Pub. Date: Nov. 21, 2013

(54) THIN DISPLAY DEVICE

(71) Applicant: Panasonic Corporation, Osaka (JP)

(72) Inventors: Hisanori Sasaki, Osaka (JP); Yoshikazu Yamano, Osaka (JP); Motonari Ogura, Osaka (JP)

(73) Assignee: Panasonic Corporation, Osaka (JP)

(21) Appl. No.: 13/946,152

(22) Filed: Jul. 19, 2013

Related U.S. Application Data
(63) Continuation of application No. PCT/JP2013/000102, filed on Jan. 11, 2013.

(30) Foreign Application Priority Data
Mar. 13, 2012 (JP) 2012-055549

(51) Int. Cl. H05K 5/02; H05K 5/00

(52) U.S. Cl. CPC H05K 5/0217; H05K 5/0017
USPC 361/679.01

(57) ABSTRACT

A thin display device includes a display unit and an exterior case. The exterior case accommodates the display unit therein. When accommodated in a packing case, the exterior case 8 is held by shock-absorbing members at upper and lower corner regions. A back cabinet of the exterior case is mounted on the display unit so as to cover a back side of the display unit. The display unit includes bead portions for reinforcement on peripheries of the upper and lower corner regions held by the shock-absorbing members. The display unit also includes a plurality of screw-fitting portions on the bead portions. The back cabinet is threadedly mounted on the screw-fitting portions. It is possible to prevent the thin display device from being damaged by a mechanical impact during transportation.

### CROSS-REFERENCE TO RELATED APPLICATIONS

This is a continuation application of International Application No. PCT/JP2013/000102, with an international filing date of Jan. 11, 2013, which claims priority of Japanese Patent Application No.: 2012-055549 filed on Mar. 13, 2012, the content of which is incorporated herein by reference.

### BACKGROUND

1. Technical Field

The present disclosure relates to a thin display device such as a liquid crystal display device and a plasma display device used for a television receiver and a monitor device or the like.

2. Description of Related Art

Needs for liquid crystal display devices has been growing as professional-use as well as residential-use flat-type video display unit.

Generally, the liquid crystal display device is configured in such a manner that a backlight device as a surface light source is disposed on a back side of a flat liquid crystal display panel to configure a display module, and this display module is accommodated in a thin casing composed of a front cabinet and a back cabinet (see JP 2009-139426 A).

### SUMMARY

This disclosure prevents a thin display device from being damaged by a mechanical impact during transportation.

The liquid crystal display devices have been made much thinner along with the popularization of a backlight device using LEDs. In view of outward appearance design, products of narrow frame design, in which a periphery of a front cabinet is narrowed as compared with an image display region, are increasing.

Since being made much thinner compared with conventional devices and adapting the narrow frame design, the liquid crystal display devices and other display devices (e.g., plasma display devices) tend to deteriorate in mechanical strength as a display. This causes a problem that the device is damaged by a mechanical impact during transportation.

The present disclosure has been accomplished in view of such circumstances and prevents a thin display device from being damaged by a mechanical impact during transportation.

The present disclosure provides a thin display device comprising a display unit including a flat display panel and a drive circuit block for displaying an image on the display panel, and an exterior case for accommodating the display unit, upper and lower corner regions of the exterior case being held by shock-absorbing members separately disposed at these regions when the exterior case is accommodated in a packing case, wherein the exterior case includes a back cabinet mounted on the display unit to cover a back surface of the display unit, wherein the display unit includes bead portions for reinforcement provided on peripheries of the upper and lower corner regions to be held by the shock-absorbing members, and a plurality of screw-fitting portions provided on the bead portions, the back cabinet being threadedly mounted on the screw-fitting portions, and wherein positions of the bead portions on the display unit are set so that upper and lower ends of the shock-absorbing members arranged on the upper and lower corner regions of the exterior case are positioned above the bead portions.

The present disclosure can achieve effective protection of a thin display device from a mechanical impact during transportation, thereby preventing a display panel from being damaged.

### BRIEF DESCRIPTION OF THE DRAWINGS

FIG. 1 is a perspective view showing outward appearance of a liquid crystal display device according to an embodiment of the present disclosure;

FIG. 2 is an exploded perspective view of the liquid crystal display device;

FIG. 3 is a block diagram showing a circuit block of an entire configuration of the liquid crystal display device;

FIG. 4 is a perspective view showing a state where a display device body is accommodated in a packing case;

FIG. 5 is a rear view showing a positional relation between the display device body and a shock-absorbing member;

FIG. 6 is a sectional view in FIG. 5 (taken along line VI-VI);

FIG. 7 is a rear view showing a display unit from which a back cabinet of the liquid crystal display device is removed; and

FIG. 8 is an enlarged view of FIG. 7.

### DETAILED DESCRIPTION

A thin display device according to an embodiment of the present disclosure will be described with reference to the drawings by taking an example of a display module used for a liquid crystal display device. Excessively detailed description will be omitted if applicable. For example, detailed description of an already known matter and redundant description of essentially the same configurations will be omitted if applicable. This is for preventing the following description from being unnecessarily redundant, and for facilitating understanding of those who skilled in the art. The present inventors provide the accompanying drawings and the following description for those skilled in the art to fully understand the present disclosure and do not intend to limit the subject matter defined in claims by the attached drawings and the following description.

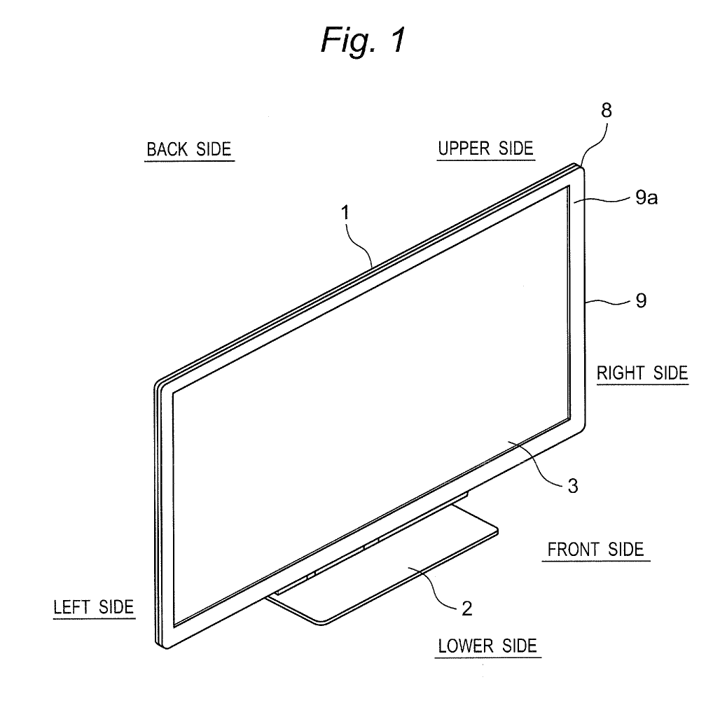

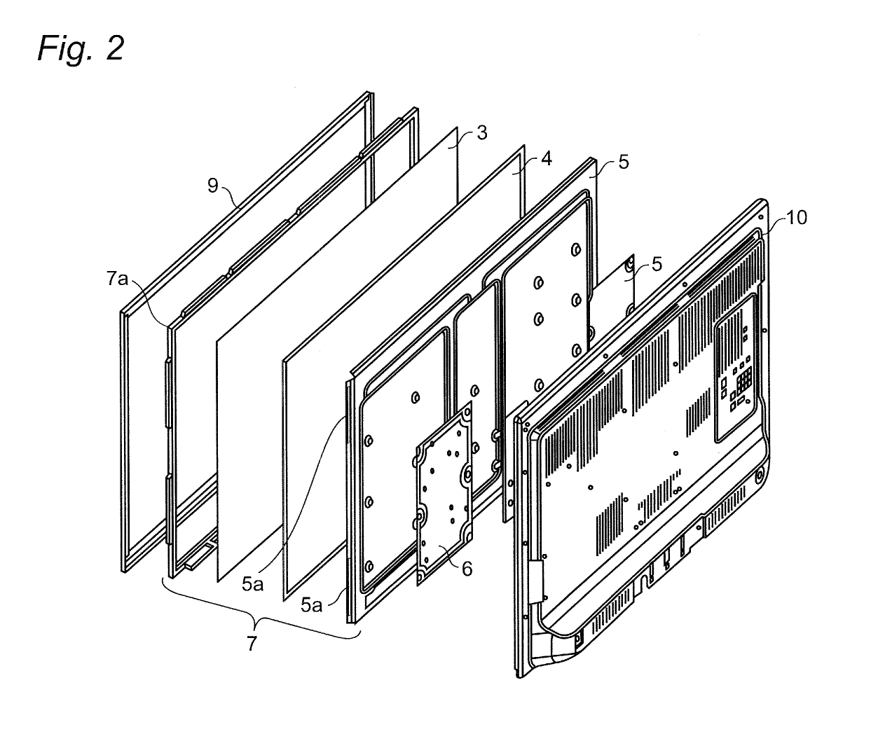

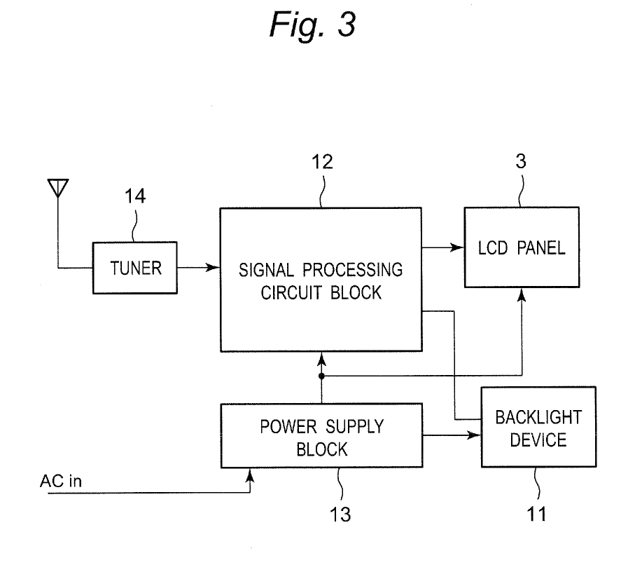

FIG. 1 shows outward appearance of a liquid crystal display device, which is a completed product, in the embodiment of the present disclosure. FIG. 2 is an exploded perspective view of a display device body. FIG. 3 shows a circuit block of an entire configuration of the liquid crystal display device. In the following description, when a direction is referred to using expressions such as “upper side”, “lower side”, “left side”, “right side”, “front side” and “rear side”, these expressions are used based on a case where the liquid crystal display device is disposed in a posture of a normal using state and a liquid crystal display panel 3 is viewed from front.

As shown in FIGS. 1 and 2, the liquid crystal display device includes a display device body 1 and a stand 2 which holds the display device body 1 in its standing state. The display device body 1 includes a display unit 7. The display unit 7 includes a liquid crystal display panel (referred to as merely “display panel” hereinafter) 3, which is a flat display panel, a light guide plate 4 configuring a backlight device, a metal frame 5 which holds the liquid crystal display panel 3 and the light guide plate 4, and a drive circuit block 6 for displaying an image on the liquid crystal display panel 3. The display unit 7 is accommodated together with other parts configuring the display device body 1 in an exterior case 8 which is a resin molded article.

The exterior case 8 includes a front cabinet 9 and back cabinet 10. The front cabinet 9 is formed with an opening 9a corresponding to an image display region of the display panel 3. The back cabinet 10 is combined with the front cabinet 9 so as to cover a back side of the display unit 7. A periphery of the back cabinet 10 of the exterior case 8 is threadedly mounted on the frame 5 of the display unit 7 by means of screws so as to cover the back side of the display unit 7.

In FIG. 2, a front frame 7a made of metal holds the liquid crystal display panel 3 and the light guide plate 4 in cooperation with the frame 5.

As shown in FIG. 3, as a schematic configuration of the entire liquid crystal display device, a signal-processing circuit block 12, a power supply block 13, and a tuner 14 are provided in addition to a drive circuit for displaying an image on a display panel 3. The signal-processing circuit block 12 includes a lighting control circuit for controlling lighting of a backlight device 11. The power supply block 13 supplies power supply voltage to the display panel 3, the backlight device 11, and the signal-processing circuit block 12. The tuner 14 receives television broadcasting and supplies a reception signal to the signal-processing circuit block 12. The signal-processing circuit block 12 and the power supply block 13 are configured by mounting parts configuring circuits on the respective circuit substrates. The drive circuit block 6 provided with the signal-processing circuit block 12, the power supply block 13, and the tuner 14 is mounted on a back surface of the frame 5 of the display unit 7, and the drive circuit block 6 is disposed in a space between the display unit 7 and the back cabinet 10.

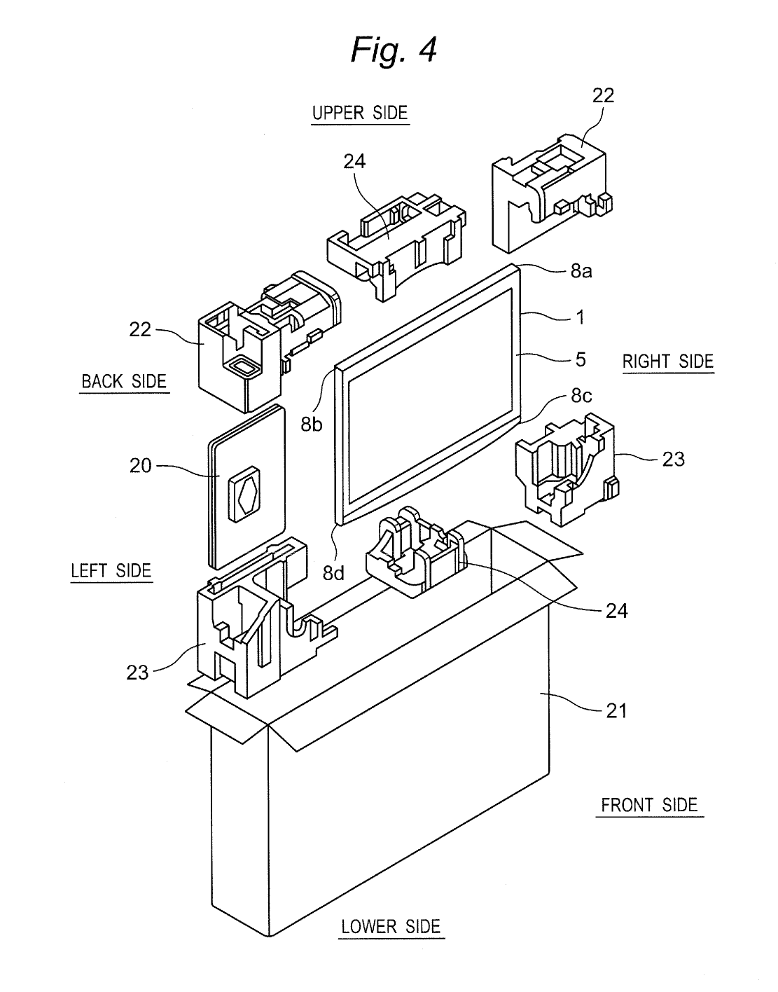

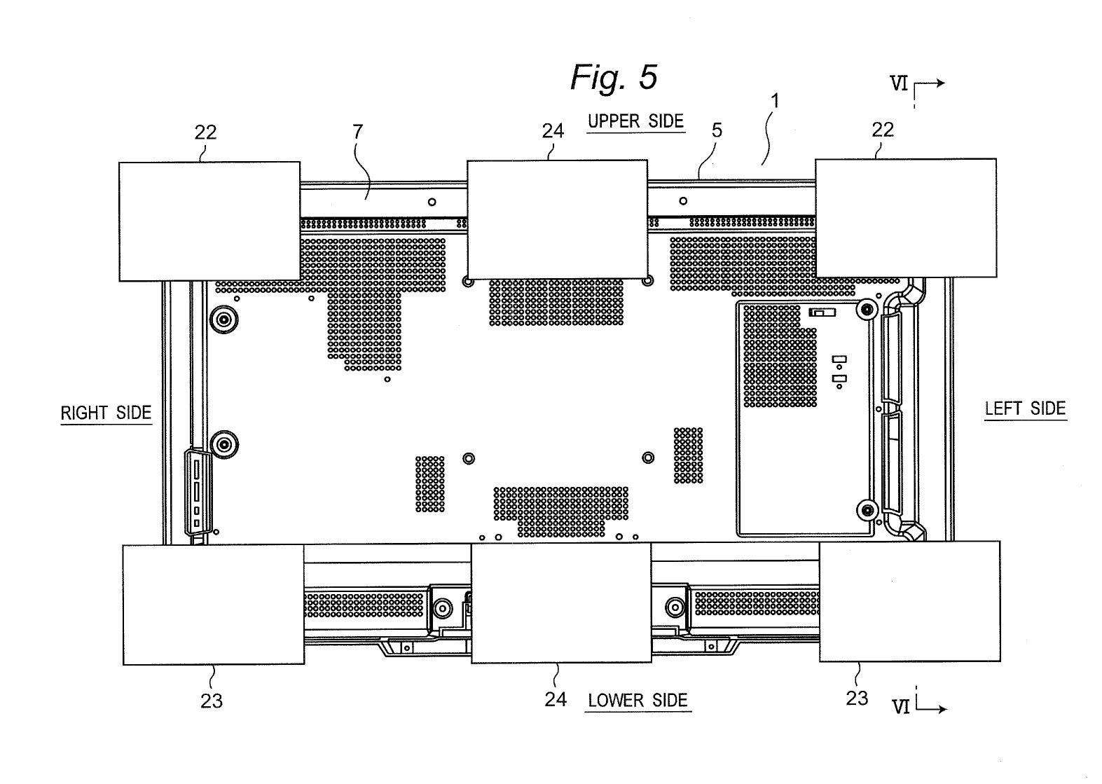

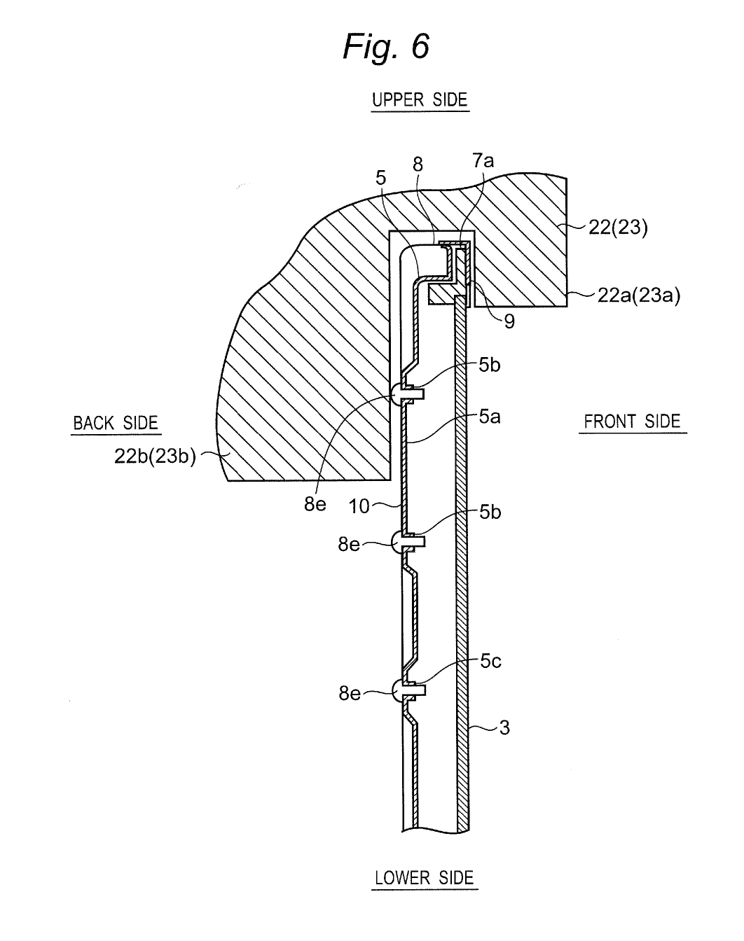

FIGS. 4, 5, and 6 are for describing a packing method of the liquid crystal display device, wherein FIG. 4 is a perspective view showing a state where the display device body is accommodated in a packing case, FIG. 5 is a plan view showing a positional relation between the display device body and a shock-absorbing member, and FIG. 6 is a sectional view (taken along line VI-VI) which is cut in the vertical direction in a packed state in FIG. 5.

As shown in FIGS. 4 to 6, the display device body 1 is covered with a packaging bag (not shown) and then, the display device body 1 is accommodated in a packing case 21 made of corrugated cardboard so as to be packed in the packing case 21 together with an accompanying item 20 such as a remote control. At this time, a pair of upper corner shock-absorbing members 22 are separately disposed at upper left and right corners of packing case 21 and a pair of lower corner shock-absorbing members 23 are separately disposed at lower left and right corners of the packing case 21. Shock-absorbing members 24 separated from the shock-absorbing members 22 and 23 are also disposed at upper and lower central portions. These shock-absorbing members 22, 23, and 24 are made of materials having at least elasticity or shock-absorbing property such as foaming polystyrene.

As shown in FIGS. 4 and 5, upper and lower corner regions 8a, 8b, 8c, and 8d of the exterior case 8 of the display device body 1 are held by shock-absorbing members 22 and 23 disposed at the upper and lower corners of the packing case 21. More specifically, the upper corner regions 8a and 8b of the exterior case 8 are held by the shock-absorbing members 22, and the lower corner regions 8c and 8d of the exterior case 5 are held by the shock-absorbing members 23.

As shown in FIG. 6, a periphery of the back cabinet 10 of the exterior case 8 is mounted on the frame 5 by means of screws 8e so as to cover the back side of the display unit 7. At peripheries of the frame 5 of the display unit 7 held by the upper corner shock-absorbing members 22 and the lower corner shock-absorbing members 23, i.e., at four corners of the frame 5, bead portions 5a for reinforcement are formed by drawing. Each of the bead portions 5a is provided with a plurality of (two in FIG. 6) screw-fitting portions 5b on which the back cabinet 10 is threadedly mounted. A screw-fitting portion 5c is provided at a position other than the bead portion 5a.

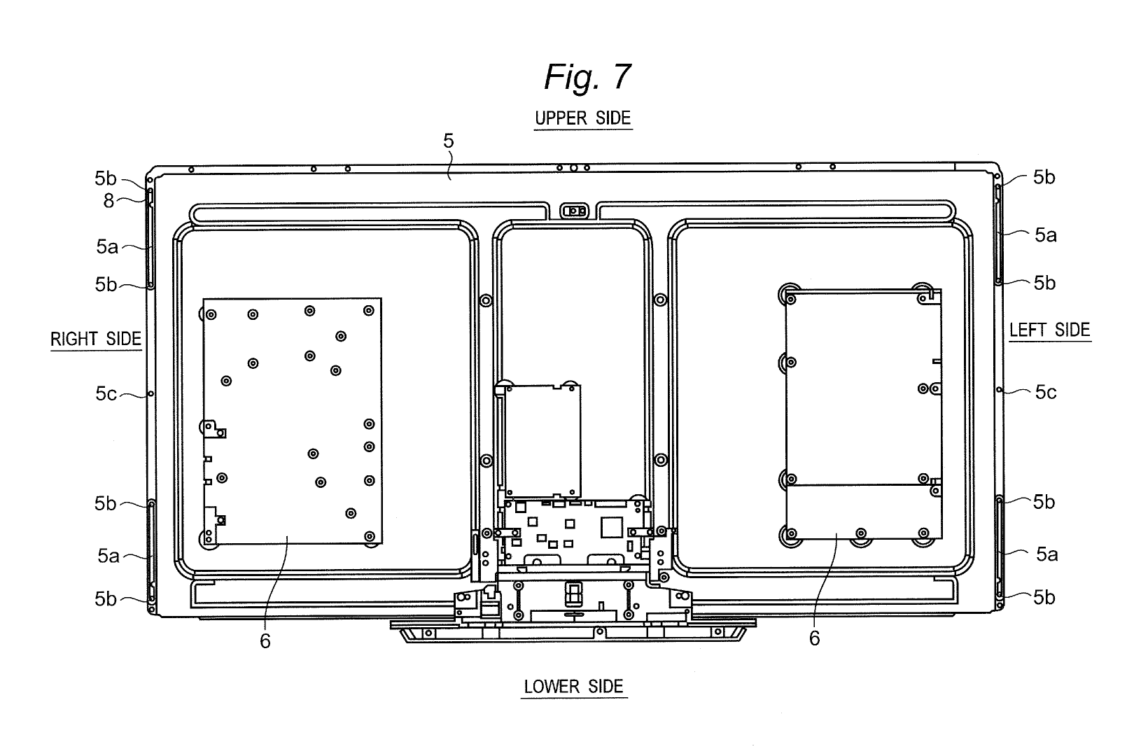

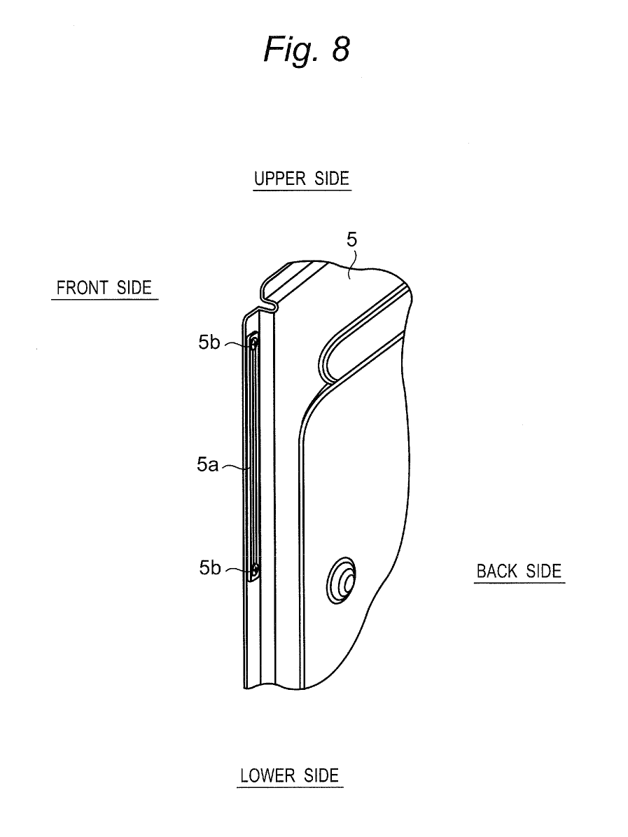

FIG. 7 is a plan view showing the display unit with the back cabinet of the liquid crystal display device being removed. FIG. 8 is an enlarged perspective view of FIG. 7.

As shown in FIGS. 7 and 8, a circuit substrate of the drive circuit block 6 of the display unit 7 is mounted on the frame 5. The bead portions 5a for reinforcement are formed on the periphery of the frame 5 held by the upper corner shock-absorbing members 22 and the lower corner shock-absorbing members 23 by carrying out drawing so that a portion of the frame 5 swells toward the back side. In this embodiment, each of the bead portions 5a has a thin and long band-like shape which is elongated in the vertical direction as viewed from the back side and which has a substantially constant width. Two screw-fitting portions 5b are formed at near upper and lower ends in the bead portion 5a. The screw-fitting portions 5b are formed by partially projecting the bead portions 5a toward the back side.

As shown in FIG. 6, the shock-absorbing members 22 and the shock-absorbing members 23 are disposed on the display device body 1 so that wall portions 22a (23a) on the front side hold the front cabinet 9 of the display device body 1 and wall portions 22b (23b) on the back side hold the bead portions 5a of the frame 5 of the display device body 1. The wall portions 22b (23b) on the back side of shock-absorbing members 22 and the shock-absorbing members 23 are disposed so that ends thereof in the vertical direction are located between the two screw-fitting portions 5b provided on the bead portion 5a.

As the exterior case 8 is narrowed, a width of the periphery of the exterior case 8 is narrowed resulting in that strength of the exterior case 8 is lowered. Further, since the back cabinet 10 is threadably mounted on the display unit 7, it is necessary to form a hole in the back cabinet 10. This also causes lowering in strength.

In this disclosure, the periphery of the frame 5 of the display unit 7 is provided with the bead portions 5a for reinforcement, and the periphery of the frame 5 is held by the upper corner shock-absorbing members 22 and the lower corner shock-absorbing members 23. The bead portion 5a is provided with the plurality of screw-fitting portions 5b on which the back cabinet 10 is threadedly mounted. This fixing structure can enhance strength against stress causing deformation of the display device body 1. As a result, even when the exterior case 8 as the frame is narrowed, strength of the display device body 1 against the stress can sufficiently be secured, and thereby it is possible to prevent the display device body 1 from being damaged during transportation.

As described above, in the present disclosure, the thin display device can be thinned. Even if employing the narrow frame design causes lowering in mechanical strength, damages caused by a mechanical impact during transportation can be prevented.

As described above, the present disclosure is useful for preventing a thin display device from being damaged during transportation.

Although the present disclosure has been fully described in connection with the preferred embodiments thereof with reference to the accompanying drawings, it is to be noted that various changes and modifications are apparent to those skilled in the art. Such changes and modifications are to be understood as included within the scope defined by the appended claims unless they depart therefrom.

What is claimed is:

1. A thin display device comprising:
a display unit including a flat display panel and a drive circuit block for displaying an image on the display panel; and
an exterior case for accommodating the display unit, upper and lower corner regions of the exterior case being held by shock-absorbing members separately disposed at these regions when the exterior case is accommodated in a packing case,
wherein the exterior case includes a back cabinet mounted on the display unit to cover a back surface of the display unit,
wherein the display unit includes bead portions for reinforcement provided on peripheries of the upper and lower corner regions to be held by the shock-absorbing members, and a plurality of screw-fitting portions provided on the bead portions, the back cabinet being threadedly mounted on the screw-fitting portions, and
wherein positions of the bead portions on the display unit are set so that upper and lower ends of the shock-absorbing members arranged on the upper and lower corner regions of the exterior case are positioned above the bead portions.

2. The thin display device according to claim 1, wherein the display unit includes a frame which is disposed on a back surface side of the display panel and on which a circuit substrate of the drive circuit block is mounted, and
wherein the bead portions and the screw-fitting portions are provided in peripheries of the frame.

3. The thin display device according to claim 2, wherein the bead portions are formed by partially swelling the peripheries of the frame toward a back side.

4. The thin display device according to claim 3, wherein the screw-fitting portions are formed by partially projecting the bead portions toward the back side.
